(19) United States
(12) Patent Application Publication
(10) Pub. No.: US 2024/0001567 A1
(43) Pub. Date: Jan. 4, 2024

(54) PICK-AND-PLACE HANDLER WITH REDUCED ELECTROMAGNETIC INTERFERENCE

(71) Applicant: Skyworks Solutions, Inc., Irvine, CA (US)

(72) Inventors: Jose Juan Montalban Castellon, Mexicali (MX); Gabriela Enriquez Gonzalez, Mexicali (MX); Enrico Marcelo Sy, Mexicali (MX); Zelman Hernandez Castro, Imperial, CA (US); Emigdio Villaescuza Elias, Mexicali (MX)

(21) Appl. No.: 18/214,996

(22) Filed: Jun. 27, 2023

Related U.S. Application Data
(60) Provisional application No. 63/367,458, filed on Jun. 30, 2022.
(60) Provisional application No. 63/367,464, filed on Jun. 30, 2022.

(51) Int. Cl. B25J 19/00; B25J 9/02; B25J 15/00; B25J 15/02

(52) U.S. Cl. CPC B25J 19/0075; B25J 9/023; B25J 15/0019; B25J 15/02

(57) ABSTRACT

A handler is disclosed. The handler can include a robotic arm. The robotic arm can be coupled to a driver. The handler can include a nozzle. The nozzle can be coupled to the robotic arm. The nozzle can include a carbon fiber reinforced polymer and be configured to pick-and-place an electronic component to a carrier. The handler can include a robotic arm filter that is coupled between the robotic arm and a frame of the handler. The nozzle is configured to pick-and-place an electronic component to a carrier. The handler can include a plurality of filters. The plurality of filters can include a robotic arm filter, a driver filter, a chassis ground filter, and/or a packaged filter. The robotic arm filter can be coupled between the robotic arm and a frame of the handler. The driver filter can be coupled between the driver and the frame. The chassis ground filter can be coupled between the driver and earth ground. The packaged filter can be positioned between the nozzle and the earth ground. The packaged filter can include a magnetic toroid core and wires wrapped around the magnetic toroid core.

### INCORPORATION BY REFERENCE TO ANY PRIORITY APPLICATIONS

Any and all applications for which a foreign or domestic priority claim is identified in the Application Data Sheet as filed with the present application, including U.S. Provisional Patent Application No. 63/367,458, filed Jun. 30, 2022, titled “PICK-AND-PLACE HANDLER WITH REDUCED ELECTROMAGNETIC INTERFERENCE,” and U.S. Provisional Patent Application No. 63/367,464, filed Jun. 30, 2022, titled “HANDLER WITH FILTERS FOR REDUCED ELECTROMAGNETIC INTERFERENCE” are hereby incorporated herein by reference under 37 CFR 1.57 in their entirety.

### BACKGROUND

### Technical Field

Embodiments of this disclosure relate to a thermal connection in an integrated device die.

### Description of Related Technology

Electronic components, such as semiconductor devices, can be mounted to a printed circuit board (PCB) using a pick-and-place handler or handling equipment. The handler can include moving parts that are electrically controlled to quickly and accurately place the electronic components to designated locations on the PCB. The electronic components can include electrostatic sensitive devices. Electromagnetic interference (EMI) in the handler can damage the sensitive devices thereby hindering yield of manufacturing packaged devices or assemblies.

### SUMMARY

The innovations described in the claims each have several aspects, no single one of which is solely responsible for its desirable attributes. Without limiting the scope of the claims, some prominent features of this disclosure will now be briefly described.

In one or more embodiments, a handler is disclosed. The handler can include a robotic arm that is coupled to a driver, a nozzle that is coupled to the robotic arm, and a robotic arm filter coupled between the robotic arm and a frame of the handler. The nozzle includes a carbon fiber reinforced polymer and is configured to pick-and-place an electronic component to a carrier.

In other embodiments, the handler further includes a chassis ground filter that is coupled between the driver and earth ground. In yet other embodiments, the handler further includes a driver filter that is coupled between the driver and the frame. In further embodiments, the driver includes a servo motor.

In some embodiments, the robotic arm includes an x-movement arm that is configured to move the nozzle in an x-direction, a y-movement arm that is configured to move the nozzle in a y-direction, and a z-movement arm that is configured to move the nozzle in a z-direction. Each of the x-movement, y-movement, and z-movement arms can be coupled to a filter. Each of the x-movement, y-movement, and z-movement arms is coupled to a corresponding motor of the driver. In other embodiments, the robotic arm filter is a four robotic arm filter.

In additional embodiments, a handler is disclosed. The handler can include a robotic arm that is coupled to a driver, and a plurality of filters including a driver filter and a chassis ground filter. The driver filter is coupled between the driver and a frame of the handler. The chassis ground filter is coupled between the driver and earth ground.

In other embodiments, the handler further includes a nozzle that is coupled to the robotic arm. The nozzle is configured to pick and place an electronic component to a carrier. The nozzle can include a carbon fiber reinforced polymer. The driver can include a servo motor. The robotic arm can include an x-movement arm that is configured to move the nozzle in an x-direction, a y-movement arm that is configured to move the nozzle in a y-direction, and a z-movement arm that is configured to move the nozzle in a z-direction. Each of the x-movement, y-movement, and z-movement arms can be coupled to a filter. Each of the x-movement, y-movement, and z-movement arms can be coupled to a corresponding motor of the driver.

In yet other embodiments, the plurality of filters include a robotic arm filter. In further embodiments, the robotic arm filter can be coupled between the robotic arm and the frame of the handler. In yet further embodiments, the robotic arm filter can be a four robotic arm filter.

In certain embodiments, a handler is disclosed. The handler can include a robotic arm that has a nozzle, and a packaged filter that is positioned between the nozzle and earth ground. The packaged filter includes a magnetic toroid core and wires wrapped around the magnetic toroid core.

In other embodiments, the handler further includes a driver filter and a chassis ground filter. The robotic arm can be coupled to a driver. In yet other embodiments, the driver filter can be coupled between the driver and a frame of the handler. In further embodiments, the chassis ground filter can be coupled between the driver and earth ground. The nozzle can include a carbon fiber reinforced polymer.

In yet further embodiments, the robotic arm can include an x-movement arm that is configured to move the nozzle in an x-direction, a y-movement arm that is configured to move the nozzle in a y-direction, and a z-movement arm that is configured to move the nozzle in a z-direction. In some embodiments, the driver can include first to third servo motors that are respectively coupled to the x-movement arm, the y-movement arm, and the z-movement arm.

### BRIEF DESCRIPTION OF THE DRAWINGS

Embodiments of this disclosure will now be described, by way of non-limiting example, with reference to the accompanying drawings.

FIG. 1 shows an example pick-and-place handler 1 that includes a robotic arm.

FIG. 2 is a schematic block diagram showing a pick-and-place handler according to an embodiment.

FIG. 3 is a schematic plan view of a packaged filter without a lid to show internal components, according to an embodiment.

FIGS. 4A and 4B show schematic plan views of packaged filters without a lid to show internal components, according to various embodiments.

FIG. 4C is a schematic plan view of a filter according to an embodiment.

FIG. 4D is a graph showing measured voltage levels at a handler nozzle of a handler with and without a filter implemented in the handler.

FIG. 5 is a table of experimental results showing EMI levels for various configurations of a pick-and-place handler.

FIG. 6 shows at least a portion of an impedance model of a grounding network in a handler.

FIG. 7 is a schematic perspective view of a pick-and-place handler according to an embodiment.

### DETAILED DESCRIPTION OF CERTAIN EMBODIMENTS

The following description of certain embodiments presents various descriptions of specific embodiments. However, the innovations described herein can be embodied in a multitude of different ways, for example, as defined and covered by the claims. In this description, reference is made to the drawings where like reference numerals can indicate identical or functionally similar elements. It will be understood that elements illustrated in the figures are not necessarily drawn to scale. Moreover, it will be understood that certain embodiments can include more elements than illustrated in a drawing and/or a subset of the elements illustrated in a drawing. Further, some embodiments can incorporate any suitable combination of features from two or more drawings. Silicon on insulator die silicon on insulator transistor.

Static electricity can be built in human body, components of a machine, or a work station, etc. The static electricity can be discharged to electrostatic sensitive devices causing damage to the devices. The electrostatic discharge (ESD) can hinder yield of manufacturing packaged devices or assemblies. Reduction of the ESD is known in the industry. Electric overstress (EOS) is another issue associated with electromagnetic interference (EMI). The EOS is a different cause of damaging the components and devices being manufactured at a manufacturing site.

The EOS can be caused when the EMI is present in the manufacturing site. The EMI can be caused by power lines in the manufacturing site, cellular phone used in or near the manufacturing site, and/or parts inside pick-and-place handler or handling equipment. For example, commutation power, dimmers and/or heat control, switched mode power supplies (SMPS), uninterruptable power supplies (UPS), and/or servo or variable frequency motors can cause the EMI within the handler. The EMI can damage the electronic components that is being handled through a grounding of the handler.

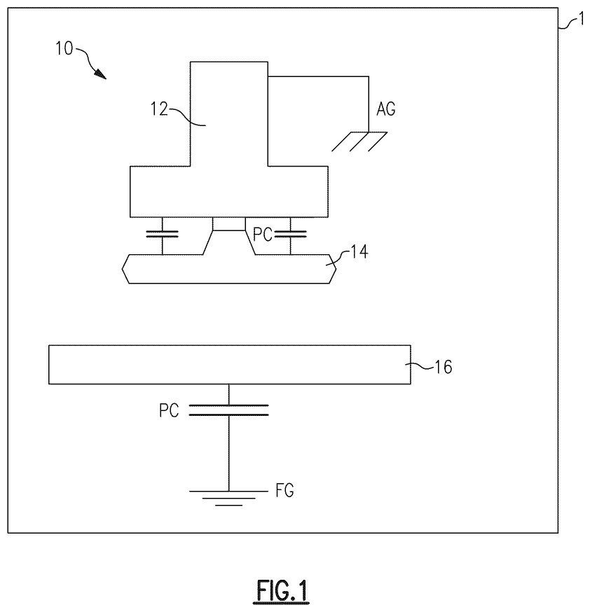

FIG. 1 shows an example pick-and-place handler 1 that includes a robotic arm 10. The robotic arm has a nozzle 12 that can pick up an electronic component 14, such as a silicon die, to place the component 14 onto a carrier (e.g., a printed circuit board (PCB) 16). The nozzle 12 can be grounded through an arm ground (AG), and the PCB 16 can be grounded through a frame ground (FG). There can be parasitic capacitance (PC) created between the component 14 and the nozzle 12. When the component 14 is placed on the PCB 16 (or be in contact with a shuttle or a test socket), the energy can be discharged through the component 14 thereby damaging the component 14 due to the EOS.

The EOS is not the only problem caused by the EMI. For example, the EMI can cause a high-frequency noise which can add noise to useful signals when testing the devices. Various embodiments disclosed herein can reduce such risks and problems associated with the EMI, and provide, for example, more accurate testing.

A main difference between the electrostatic discharge (ESD) and the electric overstress (EOS) is that while the ESD is caused by a static charge, the EOS is caused by voltage and current in, for example, the tools used in the manufacturing site. EOS can provide significant energy continuously into the device, and cause damages at much lower exposure levels than ESD. The concept of EOS in a manufacturing site and how to reduce the EOS are not well-understood, and it can be challenging to control the EMI-caused EOS.

Reducing the EMI in a semiconductor manufacturing site can contribute to preventing or mitigating damage to the devices being manufactured. SEMI E176-1017 provides information regarding how to assess and minimize the EMI in a semiconductor manufacturing environment. The SEMI E176-1017 standard provides recommendations on EMI levels at the semiconductor manufacturing environment. The present disclosure may refer to the EMI levels set forth under the SEMI E176-1017 standard for convenience. There can be radiation emission and conductive emission that can cause EMI. Typically, smaller devices are more susceptible to the EMI than larger devices. In some applications, for a device that has a geometry size of about 28.3 nm or more (which can be referred to Category 1 under the SEMI E176-1017 standard), maintaining a near field radiated peak emission of about 2 V/m or less, a near field radiated continuous emission of about 1 V/m or less, a far field radiated peak emission of about 1 V/m or less, a far field radiated continuous emission of about 0.3 V/m or less, a conducted peak emission of about 0.3 V or less, a conducted continuous emission of about 90 dBμV or 31.6 mV or less, or a ground EMI current of about 50 mA or less, may be preferred. In some applications, for a device that has a geometry size of about 14.2 nm to 28.3 nm (which can be referred to Category 2 under the SEMI E176-1017 standard), maintaining a near field radiated peak emission of about 1.5 V/m or less, a near field radiated continuous emission of about 0.7 V/m or less, a far field radiated peak emission of about 0.8 V/m or less, a far field radiated continuous emission of about 0.3 V/m or more, a conducted peak emission of about 0.2 V or less, a conducted continuous emission of about 80 dBμV or 10 mV or less, or a ground EMI current of about 20 mA or less, may be preferred. In some applications, for a device that has a geometry size of about 10 nm to 14.2 nm (which can be referred to Category 3 under the SEMI E176-1017 standard), maintaining a near field radiated peak emission of about 1 V/m or less, a near field radiated continuous emission of about 0.5 V/m or less, a far field radiated peak emission of about 0.7 V/m or less, a far field radiated continuous emission of about 0.2 V/m or more, a conducted peak emission of about 0.1 V or less, a conducted continuous emission of about 70 dBμV or 3.16 mV or less, or a ground EMI current of about 10 mA or less, may be preferred. In some applications, for a device that has a geometry size of about 7.7 nm to 10 nm (which can be referred to Category 4 under the SEMI E176-1017 standard), maintaining a near field radiated peak emission of about 0.7 V/m or less, a near field radiated continuous emission of about 0.5 V/m or less, a far field radiated peak emission of about 0.5 V/m or less, a far field radiated continuous emission of about 0.2 V/m or more, a conducted peak emission of about 0.1 V or less, a conducted continuous emission of about 70 dBμV or 3.16 mV or less, or a ground EMI current of about 5 mA or less, may be preferred. Accordingly, minimizing the EMI can be especially significant for smaller devices.

One solution to mitigate the EMI caused EOS is to implement an incoming line filtering at power supply line of the handling equipment. However, such filtering cannot mitigate EMI that occurs in or within the handling equipment.

Various embodiments disclosed herein relate to reducing EMI within a handling equipment. In some embodiments, filters can be positioned at various locations within the handling equipment, or materials of certain parts of the handling equipment can be selected, in order to reduce the EMI at a tip of the handling equipment for a pick and place operation. For example, embodiments disclosed herein can enable the handling equipment to reduce electric overstress (EOS), a high-frequency noise, or other EMI-caused issues.

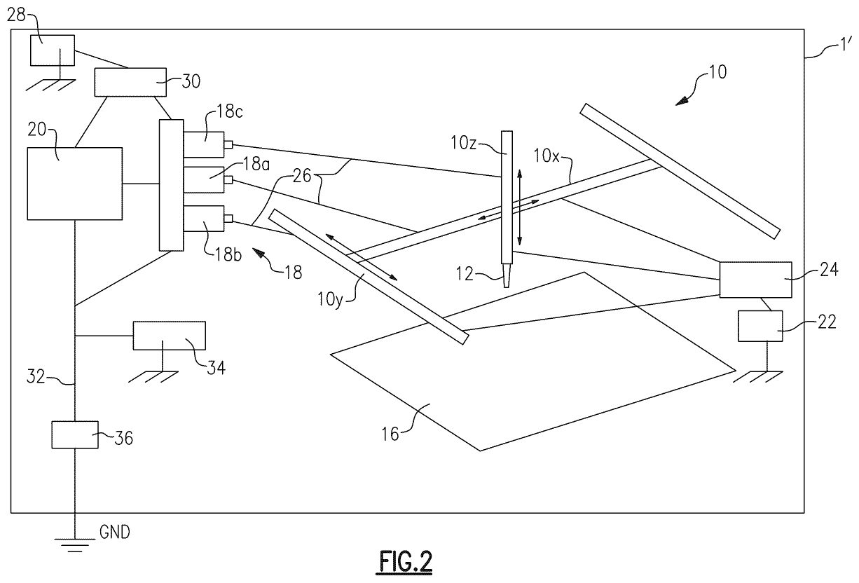

FIG. 2 is a schematic block diagram showing a pick-and-place handler 1′ according to an embodiment. The handler 1′ can include a robotic arm 10 that includes an x-movement arm 10x, a y-movement arm 10y, and a z-movement arm 10z. The robotic arm 10 is coupled to a driver 18. The x-movement arm 10x, the y-movement arm 10y, and the z-movement arm 10z can be actuated by respective first, second, and third motors 18a, 18b, 18c of the driver 18. A controller 20 can control the first, second, and third motors 18a, 18b, 18c. A nozzle 12 can be moved in three dimensions by the robotic arm 10 to pick and place an electronic component (not shown in FIG. 2) to a carrier (e.g., a printed circuit board (PCB) 16).

As described above, the electronic component can be damaged due to electrical overstress (EOS) caused by electromagnetic interference (EMI) that is present in the manufacturing site. The EMI can be caused by, for example, commutation power, dimmers and/or heat control, switched mode power supplies (SMPS), uninterruptable power supplies (UPS), and/or servo or variable frequency motors in the handler.

In some embodiments, the x-movement arm 10x and the y-movement arm 10y can be actuated by the first and second motors 18a, 18b, respectively, to move the nozzle 12 in horizontal directions, and the z-movement arm 10z can be actuated the third motor 18c to move the nozzle 12 in a vertical direction perpendicular to the horizontal directions. Each of the x-movement arm 10x, the y-movement arm 10y, and the z-movement arm 10z can be mechanically coupled to corresponding one of the first, second, and third motors 18a, 18b, 18c. In some embodiments, the first, second, and third motors 18a, 18b, 18c can include a servo motor. The mechanical connections between the robotic arm 10 and the first, second, and third motors 18a, 18b, 18c are schematically illustrated by lines 26 in FIG. 2. There may be one or more gears (not shown) between the robotic arm 10 and the first, second, and third motors 18a, 18b, 18c for controlling, for example, speed and/or torque of the movement of the nozzle 12. In some embodiments, the first, second, and third motors 18a, 18b, 18c can be connected directly to the robotic arm 10.

Each of the x-movement arm 10x, the y-movement arm 10y, and the z-movement arm 10z can be connected to a chassis ground 22. One or more filters (e.g., a filter 24) can be connected between the chassis ground 22 and the robotic arm 10 (the x-movement arm 10x, the y-movement arm 10y, and the z-movement arm 10z). In some embodiments, the filter 24 can be positioned between the nozzle 12 and the chassis ground 22. In some embodiments, the chassis ground can be a direct current (DC) ground. For example, the chassis ground can be a frame of the pick-and-place handler 1′. The filter 24 can reduce electromagnetic interference (EMI) on the nozzle 12. In some embodiments, the filter 24 can be referred to as a robotic arm filter. In some embodiments, the filter 24 can be a transient noise suppressor.

The nozzle 12 can include any suitable material. Conventionally, a metal nozzle is often used. In some embodiments, a static-dissipative material. For example, a carbon fiber reinforced polymer, such as a carbon fiber reinforced polyether ether ketone. Semitron® is an example of such static-dissipative material. The static-dissipative material, when used for the nozzle 12, can reduce the EMI on the nozzle 12 as compared to using a metal nozzle.

The first, second, and third motors 18a, 18b, 18c and the controller 20 can be connected to a chassis ground 28. For example, the chassis ground 28 can be the frame of the pick-and-place handler 1′. In some applications, the chassis ground 22 and the chassis ground 28 can be treated as functionally and/or electrically the same or generally similar ground. One or more filters (e.g., a filter 30) can be connected between the chassis ground 28 and the first, second, and third motors 18a, 18b, 18c and/or the controller 20. The filter 30 can contribute to reducing the EMI on the nozzle 12. The filter 30 can be referred to as a driver filter. In some embodiments, each of the first, second, and third motors 18a, 18b, 18c can be connected to different filters (not shown) of the one or more filters. In some embodiments, the filter 30 can be a transient noise suppressor.

The first, second, and third motors 18a, 18b, 18c and the controller 20 can be connected to earth ground (GND) through a ground line 32. In some embodiments, the ground line can be connected to a chassis ground 34. For example, the chassis ground 34 can be a machine chassis ground, which can be connected to an alternating current (AC) power connecting point of the pick-and-place handler 1′. One or more filters (e.g., a filter 36) can be connected between the GND and the first, second, and third motors 18a, 18b, 18c and/or the controller 20. The filter 34 can contribute to reducing the EMI on the nozzle 12. The filter 36 can be referred to as a chassis ground filter. In some embodiments, the filter 36 can be a transient noise suppressor.

The pick-and-place handler 1′ can include one or more cables that connect two or more components in the pick-and-place handler 1′. The line(s) connecting two or more components as shown in FIG. 2 can represent the cable(s). The cable(s) can include a routing cable such as a copper wire or a steel wire.

The pick-and-place handler 1′ can include an insulator. The insulator can be a fiber glass insulator, a double tape insulator, and/or a bakelite insulator. In some embodiments, the insulator can insulate one or more components of the pick-and-place handler 1′ from different one or more components of the pick-and-place handler 1′. For example, the insulator can be a Bakelite Insulator that can separate the metallic picker head (e.g., the nozzle 12) from the arm (e.g., the robotic arm 10) that holds the metallic picker head in order to prevent or mitigate conductive EMI from conducting to one or more ESD sensitive devices (e.g., an component that is picked by the nozzle 12).

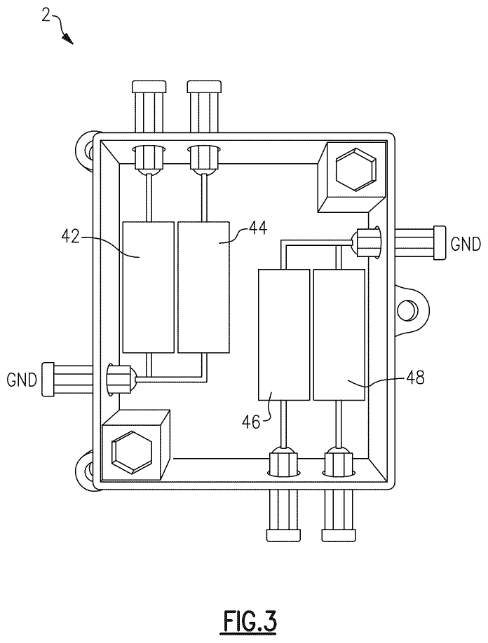

FIG. 3 is a schematic plan view of a packaged filter 2 without a lid to show internal components, according to an embodiment. The packaged filter 2 can include any suitable number of filters. Depending on the device (e.g., a pick-and-place handler) to which the packaged filter 2 is implemented, the package filter 2 can have one, two, three, four, or more filters. For example, in the illustrated embodiment, the packaged filter 2 includes a first filter 42, a second filter 44, a third filter 46, and a fourth filter 48. In some embodiments, the first and second filters 42, 44 can be coupled in parallel, and the third and fourth filter 46, 48 can be coupled in parallel. The first to fourth filters 42, 44, 46, 48 can be coupled between device picker nozzles (see the nozzle 12 in FIG. 2) and a chassis ground connection (see the chassis ground 22 in FIG. 2), for example. The packaged filter 2 illustrated in FIG. 3 is an example of a four robotic arm filter.

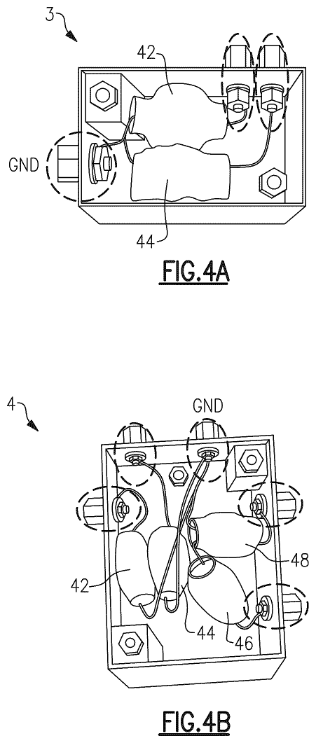

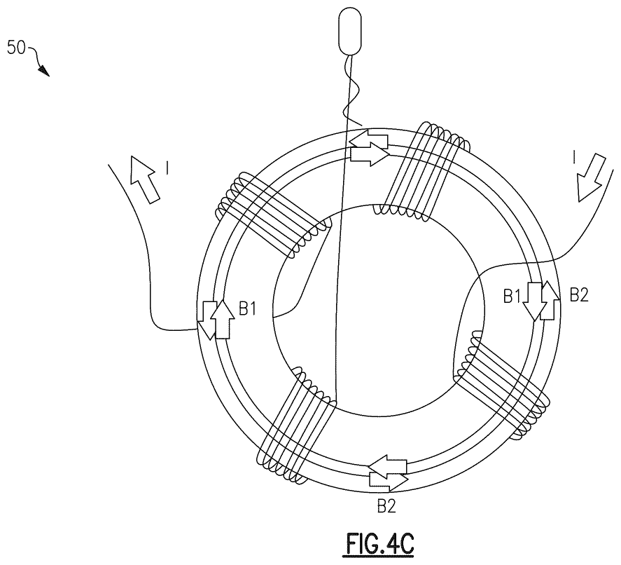

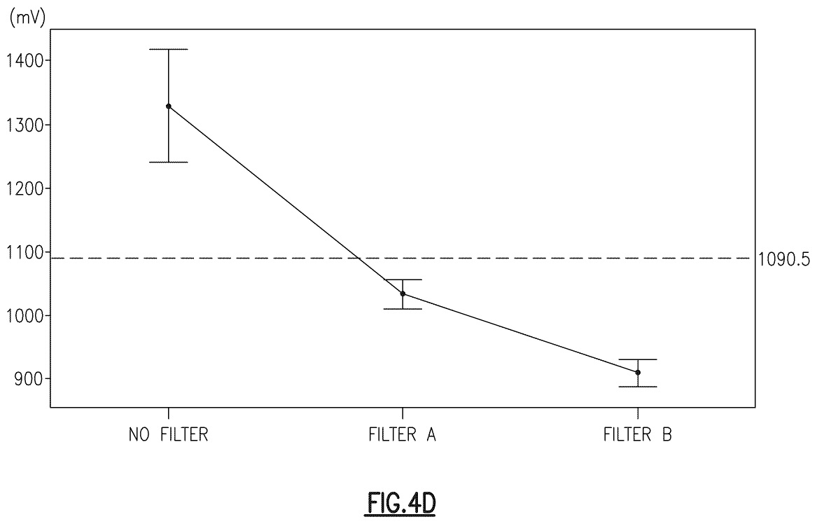

In some embodiments, each of the first to fourth filters 42, 44, 46, 48 can include a toroidal filter (see FIG. 4C). The toroidal filter can include a magnetic toroid core and wires wrapped around the magnetic toroid core. In some embodiments, one or more of the filters 24, 30, 36 can include the packaged filter 2.

FIGS. 4A and 4B show schematic plan views of packaged filters without a lid to show internal components, according to various embodiments. FIG. 4A shows a packaged filter 3 that includes a first filter 42 and a second filter 44. FIG. 4B shows a packaged filter 4 that includes a first filter 42, a second filter 44, a third filter 46, and a fourth filter 48. As shown in FIGS. 3, 4A, and 4B, two or more filters (the first to fourth filters 42, 44, 46, 48) can share the same ground node. Any suitable number of filters can be arranged in any suitable manner in a package to define a packaged filter, and any suitable number of the packaged filter can be coupled to any suitable locations of a pick-and-place handler (e.g., the pick-and-place handler 1′ shown in FIG. 2).

FIG. 4C is a schematic plan view of a filter 50 that can be implemented in a handler, such as the pick-and-place handler 1′, in accordance with various embodiments disclosed herein. For example, the first to fourth filters 42, 44, 46, 48 of FIGS. 3, 4A and 4B can include the filter 50 shown in FIG. 4C. The filter 50 can include a magnetic toroid core and wires wrapped around the magnetic toroid core. The wires are wrapped such that there can be magnetic fields B1, B2. The magnetic field B1 of the filter 50 and the magnetic field B2 of the filter 50 can be derived by Ampere's law. As shown by the arrows in FIG. 4C, the magnetic field B1 has a magnetic field direction in the clockwise direction, and the magnetic field B2 has a magnetic field direction in the counterclockwise direction. Accordingly, when the magnitudes of the magnetic field B1 and the magnetic field B2 are the same, the sum of the two would be zero. An excess flux can be absorbed by at least partially or completely cancelling out the magnetic field in the filter 50. The filter 50 can be designed to have an inductance that is closely in resonant with the noise frequency as observed in the automated test systems that has no filter installed thereon. In some embodiments, the wires can be wrapped such that when the filter 50 is connected to a current source, the sum of the magnetic fields B1, B2 becomes close to zero. The filter 50 can be a transient noise suppressor or a transient noise suppression filter.

FIG. 4D is a graph showing measured voltage levels at a handler nozzle of a handler with and without a filter implemented in the handler. As shown in FIG. 4D, when no filter is used in the handler, the measured voltage level ranges from about 1.25V to about 1.42V. When a filter is implemented, the voltage level ranges from about 1V to about 1.05V for Filter A, and the voltage level ranges from about 0.9V to 0.95V for Filter B. Filter A is a conventional filter, and can be, for example, Ground Line EMI Filter GLE04-01 manufactured by OnFILTER, Inc. Filter B includes the filter 50 shown in FIG. 4C. The measured voltage levels shown in FIG. 4D indicate that implementation of a filter in the handler can significantly reduce the EMI at the handle nozzle.

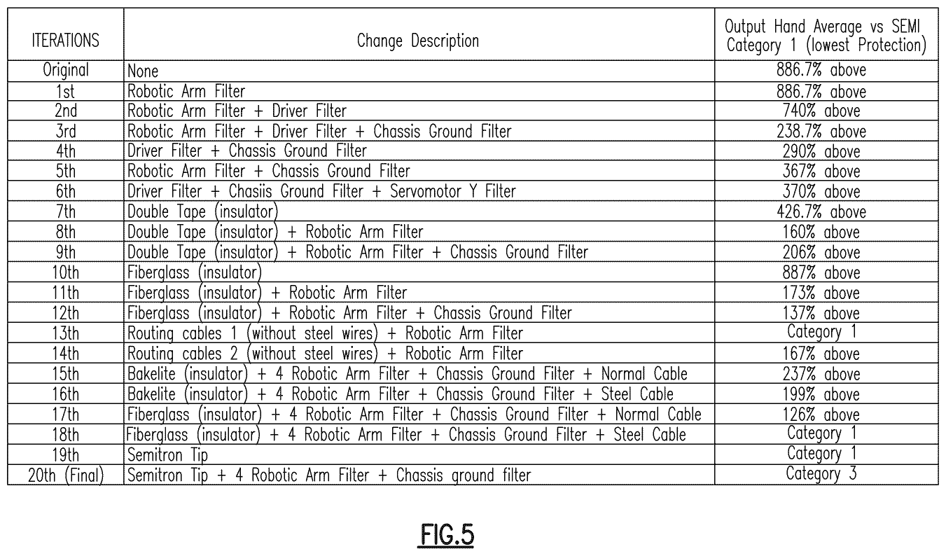

FIG. 5 is a table of experimental results showing EMI levels for various configurations of a pick-and-place handler. The left column labels the various configurations. In the original configuration, as indicated in the center column, nothing has been changed relative to a conventional baseline pick-and-place handler. The right column indicates that an EMI level of 886.7% over Category 1 of the SEMI standard.

In the first configuration, a robotic arm filter is added to the original configuration. However, no significant improvement in the EMI level was observed by the addition of the robotic arm filter alone.

In the second configuration, a robotic arm filter and a driver filter are added to the original configuration. The EMI level of the second configuration indicates that the EMI level is improved relative to the original configuration.

In the third configuration, a robotic arm filter, a driver filter, and a chassis ground filter are added to the original configuration. The EMI level of the third configuration indicates that, though still above the EMI level of Category 1, the EMI level is significantly improved relative to the original configuration.

In the fourth configuration, a driver filter, and a chassis ground filter are added to the original configuration. The EMI level of the fourth configuration indicates that the EMI level is significantly improved relative to the original configuration. The EMI levels of the third and fourth configurations indicate that the robotic arm filter, when used together with the driver filter and the chassis ground filter, can improve the EMI level.

In the fifth configuration, a robotic arm filter and a chassis ground filter are added to the original configuration. The EMI level of the fifth configuration indicates that, though still above the EMI level of Category 1, the EMI level is significantly improved relative to the original configuration.

In the sixth configuration, a driver filter, a chassis ground filter, and a servomotor Y filter are added to the original configuration. The EMI level of the sixth configuration indicates that, though still above the EMI level of Category 1, the EMI level is significantly improved relative to the original configuration.

In the seventh configuration, a double tape insulator is added to the original configuration. The EMI level of the seventh configuration indicates that, though still above the EMI level of Category 1, the EMI level is significantly improved relative to the original configuration.

In the eighth configuration, a double tape insulator and a robotic arm filter are added to the original configuration. The EMI level of the eighth configuration indicates that, though still above the EMI level of Category 1, the EMI level is significantly improved relative to the original configuration.

In the ninth configuration, a double tape insulator, a robotic arm filter, and a chassis ground filter are added to the original configuration. The EMI level of the ninth configuration indicates that, though still above the EMI level of Category 1, the EMI level is significantly improved relative to the original configuration.

In the tenth configuration, a fiberglass insulator is added to the original configuration. However, no improvement in the EMI level was observed by the addition of the fiberglass insulator alone.

In the eleventh configuration, a fiberglass insulator and a robotic arm filter are added to the original configuration. The EMI level of the eleventh configuration indicates that, though still above the EMI level of Category 1, the EMI level is significantly improved relative to the original configuration. The EMI level of the eleventh configuration is surprisingly well considering that the robotic arm filter alone in the first configuration and the fiber glass insulator alone in the tenth did not provide improvement to the EMI level.

In the twelfth configuration, a fiberglass insulator, a robotic arm filter, and a chassis ground filter are added to the original configuration. The EMI level of the twelfth configuration indicates that, though still above the EMI level of Category 1, the EMI level is significantly improved relative to the original configuration.

In the thirteenth configuration, a routing cable 1 (without steel wires) and a robotic arm filter are added to the original configuration. The EMI level of the thirteenth configuration indicates that the EMI level is significantly improved relative to the original configuration, such that the EMI level of the thirteenth configuration is in Category 1.

In the fourteenth configuration, a routing cable 2 (without steel wires) and a robotic arm filter are added to the original configuration. The EMI level of the fourteenth configuration indicates that, though still above the EMI level of Category 1, the EMI level is significantly improved relative to the original configuration.

In the fifteenth configuration, a bakelite insulator, a four robotic arm filter (see FIG. 3), chassis ground filter, and a normal cable are added to the original configuration. The EMI level of the fifteenth configuration indicates that, though still above the EMI level of Category 1, the EMI level is significantly improved relative to the original configuration.

In the sixteenth configuration, a bakelite insulator, four robotic arm filter, chassis ground filter, and a steel cable are added to the original configuration. The EMI level of the sixteenth configuration indicates that, though still above the EMI level of Category 1, the EMI level is significantly improved relative to the original configuration.

In the seventeenth configuration, a fiber glass insulator, four robotic arm filter, chassis ground filter, and a normal cable are added to the original configuration. The EMI level of the seventeenth configuration indicates that, though still above the EMI level of Category 1, the EMI level is significantly improved relative to the original configuration.

In the eighteenth configuration, a fiber glass insulator, four robotic arm filter, chassis ground filter, and a steel cable are added to the original configuration. The EMI level of the eighteenth configuration indicates that the EMI level is significantly improved relative to the original configuration, such that the EMI level of the eighteenth configuration is in Category 1.

In the nineteenth configuration, a semitron tip is added to the original configuration. The EMI level of the nineteenth configuration indicates that the EMI level is significantly improved relative to the original configuration, such that the EMI level of the nineteenth configuration is in Category 1.

In the twentieth configuration, a semitron tip, four robotic arm filter, and a chassis ground filter are added to the original configuration. The EMI level of the twentieth configuration indicates that the EMI level is significantly improved relative to the original configuration, such that the EMI level of the twentieth configuration is in Category 3.

As observed from the experimentation results of FIG. 5, some alteration can provide different outcome when used alone or in combination with other alteration(s). For example, even when one additional feature does not show improvements, the additional feature may contribute to improving the EMI level when combined with a different feature or features. Accordingly, it can be challenging to predict what alteration would provide improvements in the EMI level.

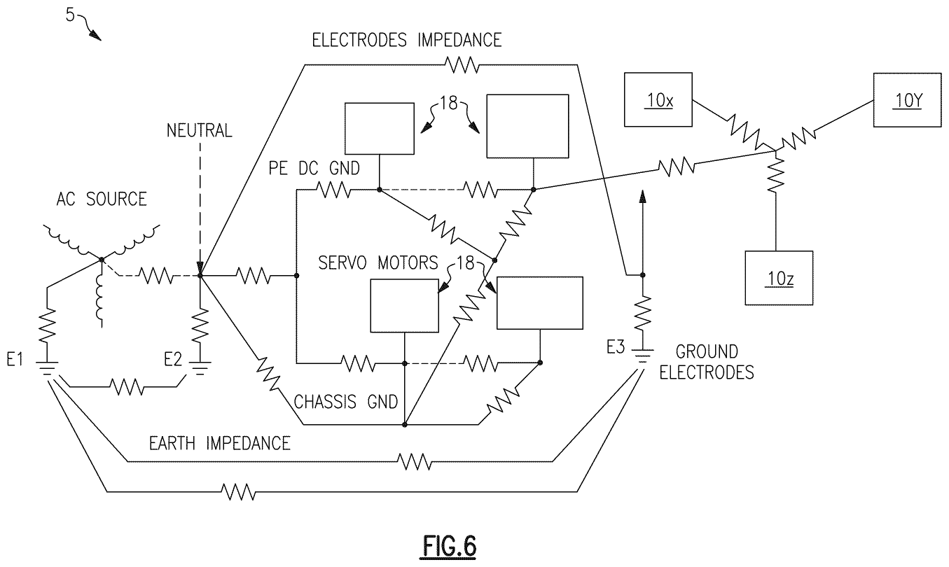

FIG. 6 shows at least a portion of an impedance model 5 of a grounding network in a handler, such as the pick-and-place handler 1′. The impedance model 5 shows an x-movement arm 10x, a y-movement arm 10y, a z-movement arm 10z, a driver 18 that can includes one or more motors (e.g., servo motors) and one or more of motor neutrals, ground nodes, a power source (e.g., an alternate current (AC) source), and a plurality of resistors disposed therebetween. One or more filters can be coupled to any suitable locations in the impedance model 5 in accordance with principle and advantages disclosed herein.

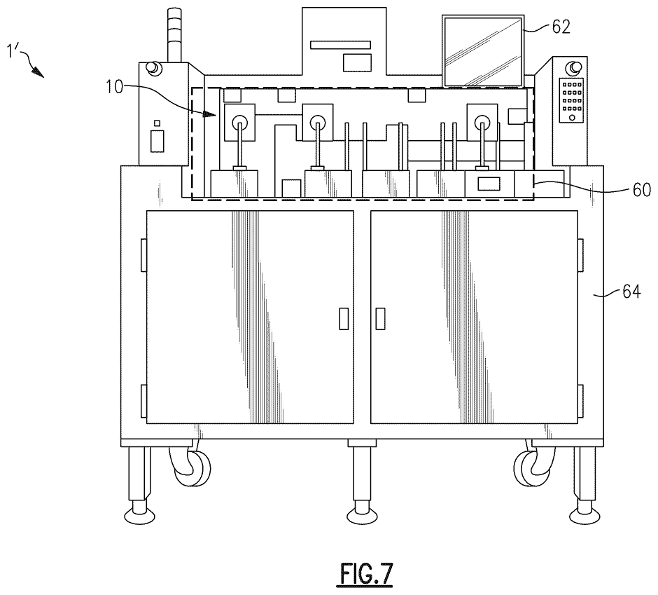

FIG. 7 is a schematic perspective view of a pick-and-place handler 1′ according to an embodiment. The pick-and-place handler 1′ can include a robotic arm 10 disposed in a handle area 60, and a user interface 62. The robotic arm 10 can include an x-movement arm 10x, a y-movement arm 10y, and a z-movement arm 10z that can be actuated by respective first, second, and third motors 18a, 18b, 18c of the driver 18 (see FIG. 2). In some embodiments, the user interface 62 can include a touch panel that allows a user to operate the pick-and-place handler 1′. The components of the pick-and-place handler 1′ can be housed, supported, framed, connected, and/or coupled by/to a frame 64 of the pick-and-place handler 1′.

Aspects of this disclosure can be implemented in various electronic devices. Examples of the electronic devices can include, but are not limited to, consumer electronic products, parts of the consumer electronic products such as packaged radio frequency modules and/or packaged filter components, uplink wireless communication devices, wireless communication infrastructure, electronic test equipment, etc. Examples of the electronic devices can include, but are not limited to, a mobile phone such as a smart phone, a wearable computing device such as a smart watch or an ear piece, a telephone, a television, a computer monitor, a computer, a modem, a hand-held computer, a laptop computer, a tablet computer, a microwave, a refrigerator, a vehicular electronics system such as an automotive electronics system, a stereo system, a digital music player, a radio, a camera such as a digital camera, a portable memory chip, a washer, a dryer, a washer/dryer, a copier, a facsimile machine, a scanner, a multi-functional peripheral device, a wrist watch, a clock, etc. Further, the electronic devices can include unfinished products.

Unless the context clearly requires otherwise, throughout the description and the claims, the words “comprise,” “comprising,” “include,” “including” and the like are to be construed in an inclusive sense, as opposed to an exclusive or exhaustive sense; that is to say, in the sense of “including, but not limited to.” The word “coupled”, as generally used herein, refers to two or more elements that may be either directly connected, or connected by way of one or more intermediate elements. Likewise, the word “connected”, as generally used herein, refers to two or more elements that may be either directly connected, or connected by way of one or more intermediate elements. As used herein, the term “approximately” intends that the modified characteristic need not be absolute, but is close enough so as to achieve the advantages of the characteristic. Additionally, the words “herein,” “above,” “below,” and words of similar import, when used in this application, shall refer to this application as a whole and not to any particular portions of this application. Where the context permits, words in the above Detailed Description using the singular or plural number may also include the plural or singular number respectively. The word “or” in reference to a list of two or more items, that word covers all of the following interpretations of the word: any of the items in the list, all of the items in the list, and any combination of the items in the list.

Moreover, conditional language used herein, such as, among others, “can,” “could,” “might,” “may,” “e.g.,” “for example,” “such as” and the like, unless specifically stated otherwise, or otherwise understood within the context as used, is generally intended to convey that certain embodiments include, while other embodiments do not include, certain features, elements and/or states. Thus, such conditional language is not generally intended to imply that features, elements and/or states are in any way required for one or more embodiments or that one or more embodiments necessarily include logic for deciding, with or without author input or prompting, whether these features, elements and/or states are included or are to be performed in any particular embodiment.

While certain embodiments have been described, these embodiments have been presented by way of example only, and are not intended to limit the scope of the disclosure. Indeed, the novel apparatus, methods, and systems described herein may be embodied in a variety of other forms; furthermore, various omissions, substitutions and changes in the form of the methods and systems described herein may be made without departing from the spirit of the disclosure. For example, while blocks are presented in a given arrangement, alternative embodiments may perform similar functionalities with different components and/or circuit topologies, and some blocks may be deleted, moved, added, subdivided, combined, and/or modified. Each of these blocks may be implemented in a variety of different ways. Any suitable combination of the elements and acts of the various embodiments described above can be combined to provide further embodiments. The accompanying claims and their equivalents are intended to cover such forms or modifications as would fall within the scope and spirit of the disclosure.

What is claimed is:

1. A handler comprising:
a robotic arm coupled to a driver;
a nozzle coupled to the robotic arm, the nozzle including a carbon fiber reinforced polymer and configured to pick-and-place an electronic component to a carrier; and
a robotic arm filter coupled between the robotic arm and a frame of the handler.

2. The handler of claim 1 further comprising a chassis ground filter coupled between the driver and earth ground.

3. The handler of claim 1 further comprising a driver filter coupled between the driver and the frame.

4. The handler of claim 1 wherein the driver includes a servo motor.

5. The handler of claim 1 wherein the robotic arm includes an x-movement arm configure to move the nozzle in an x-direction, a y-movement arm configure to move the nozzle in a y-direction, and a z-movement arm configure to move the nozzle in a z-direction.

6. The handler of claim 5 wherein each of the x-movement arm, the y-movement arm, and the z-movement arm is coupled to a filter.

7. The handler of claim 5 wherein each of the x-movement arm, the y-movement arm, and the z-movement arm is coupled to a corresponding motor of the driver.

8. The handler of claim 1 wherein the robotic arm filter is a four robotic arm filter.

9. A handler comprising:
a robotic arm coupled to a driver; and
a plurality of filters including a driver filter and a chassis ground filter, the driver filter coupled between the driver and a frame of the handler, and the chassis ground filter coupled between the driver and earth ground.

10. The handler of claim 9 further comprising a nozzle coupled to the robotic arm, the nozzle configured to pick and place an electronic component to a carrier.

11. The handler of claim 10 wherein the nozzle includes a carbon fiber reinforced polymer.

12. The handler of claim 10 wherein the driver includes a servo motor.

13. The handler of claim 10 wherein the robotic arm includes an x-movement arm configure to move the nozzle in an x-direction, a y-movement arm configure to move the nozzle in a y-direction, and a z-movement arm configure to move the nozzle in a z-direction.

14. The handler of claim 13 wherein each of the x-movement arm, the y-movement arm, and the z-movement arm is coupled to a filter.

15. The handler of claim 13 wherein each of the x-movement arm, the y-movement arm, and the z-movement arm is coupled to a corresponding motor of the driver.

16. The handler of claim 9 wherein the plurality of filters include a robotic arm filter, the robotic arm filter is coupled between the robotic arm and the frame of the handler.

17. The handler of claim 16 wherein the robotic arm filter is a four robotic arm filter.

18. A handler comprising:
a robotic arm having a nozzle; and
a packaged filter positioned between the nozzle and earth ground, the packaged filter including a magnetic toroid core and wires wrapped around the magnetic toroid core.

19. The handler of claim 18 further comprising a driver filter and a chassis ground filter, wherein the robotic arm is coupled to a driver, the driver filter is coupled between the driver and a frame of the handler, the chassis ground filter is coupled between the driver and earth ground, the nozzle includes a carbon fiber reinforced polymer.

20. The handler of claim 19 wherein the robotic arm includes an x-movement arm configured to move the nozzle in an x-direction, a y-movement arm configured to move the nozzle in a y-direction, and a z-movement arm configured to move the nozzle in a z-direction, and the driver includes first to third servo motors respectively coupled to the x-movement arm, the y-movement arm, and the z-movement arm.
